(19) United States
(12) Patent Application Publication
(10) Pub. No.: US 2012/0167958 A1
(43) Pub. Date: Jul. 5, 2012

(54) PROCESSES FOR FABRICATING SOLAR CELL MODULES WITH ENCAPSULANT HAVING RESISTANCE TO DISCOLORATION

(75) Inventors: Rebecca L. Smith, Vienna, WV (US); Jason S. Wall, Middletown, DE (US); Katherine M. Stika, Hockessin, DE (US)

(73) Assignee: E.I. DU PONT DE NEMOURS AND COMPANY, Wilmington, DE (US)

(21) Appl. No.: 13/335,226

(22) Filed: Dec. 22, 2011

Related U.S. Application Data
(60) Provisional application No. 61/426,442, filed on Dec. 22, 2010.

(51) Int. Cl. H01L 31/048; H01L 31/18

(52) U.S. Cl. 136/251; 438/66; 257/E31.117

(57) ABSTRACT

Provided herein is a process for fabricating a solar cell module that is resistant to discoloration. The solar cell module comprises a solar cell assembly and an encapsulant. The solar cell assembly in turn comprises a solar cell and a metal component. The encapsulant is in contact with the metal component. The process comprises the step of applying an additive that prevents or reduces discoloration to the encapsulant or to the metal component. Further provided is a solar cell module that is a product of the process described herein.

### CROSS-REFERENCE TO RELATED APPLICATION

This application claims priority under 35 U.S.C. §119 to U.S. Provisional Appln. No. 61/426,442, filed on Dec. 22, 2010, which is incorporated herein by reference in its entirety.

### FIELD OF THE INVENTION

The invention is directed to methods of fabricating solar cell modules. The solar cell modules comprise an encapsulant layer that is in contact with a metal component. The encapsulant layer or the metal component is treated with an additive to render the encapsulant resistant to discoloration upon prolonged contact with the metal component.

### BACKGROUND OF THE INVENTION

Several patents and publications are cited in this description in order to more fully describe the state of the art to which this invention pertains. The entire disclosure of each of these patents and publications is incorporated by reference herein.

The use of solar cells is rapidly expanding because they provide a sustainable energy resource. Solar cells can typically be categorized into two types based on the light absorbing material used, i.e., bulk or wafer-based solar cells and thin film solar cells.

Monocrystalline silicon (c-Si), poly-crystalline silicon (poly-Si), multi-crystalline silicon (mc-Si) and ribbon silicon are the materials used most commonly in forming the more traditional wafer-based solar cells. Solar cell modules derived from wafer-based solar cells often comprise a series of about 180 μm and about 240 μm thick self-supporting wafers (or cells) that are soldered together. Such a panel of solar cells, along with a layer of conductive paste and/or connecting wires deposited on its surface, is referred to as a solar cell assembly. The solar cell assembly is typically encapsulated by or sandwiched or laminated between polymeric encapsulants, which may be further sandwiched between two protective outer layers to form a weather resistant module. The protective outer layers may be formed of glass, metal sheets or films, or plastic sheets or films. In general, however, the outer layer that faces towards the sunlight should be sufficiently transparent to allow photons to reach the solar cells.

In the increasingly important alternative, thin film solar cells, the commonly used materials include amorphous silicon (a-Si), microcrystalline silicon (μc-Si), cadmium telluride (CdTe), copper indium selenide (CuInSe₂ or CIS), copper indium/gallium diselenide (CuInₓGa₍₁₋ₓ₎Se₂ or CIGS), light absorbing dyes, organic semiconductors, and the like. By way of example, thin film solar cells are described in U.S. Pat. Nos. 5,507,881; 5,512,107; 5,948,176; 5,994,163; 6,040,521; 6,123,824; 6,137,048; 6,288,325; 6,258,620; 6,613,603; and 6,784,301; and U.S. Patent Publication Nos. 20070298590; 20070281090; 20070240759; 20070232057; 20070238285; 20070227578; 20070209699; 20070079866; 20080223436; and 20080271675.

Thin film solar cells with a thickness of typically less than 2 μm are produced by depositing the semiconductor materials onto a substrate in multi-layers. Further, connecting wires, metal or metal oxide conductive coatings, or metal reflector films may be deposited over the surface of the thin film solar cells to constitute part of the thin film solar cell assembly. The substrate may be formed of glass or a flexible film and may also be referred to as a superstrate in those modules in which it faces towards the incoming sunlight. Similarly to the wafer-based solar cell modules, the thin film solar cell assemblies are further encapsulated by or laminated or sandwiched between polymeric encapsulants, which are further laminated or sandwiched between protective outer layers. In certain embodiments, the thin film solar cell assembly may be only partially encapsulated by the encapsulant, which means that only the side of the thin film solar cell assembly that is opposite from the substrate (or superstrate) is laminated to a polymeric encapsulant and then to a protective outer layer. In such a construction, the thin film solar cell assembly is sandwiched between the substrate (or superstrate) and the encapsulant on the opposite side.

Within the solar cell modules, some components may comprise an oxidizable metal or an oxidizable metal alloy. Metal components in solar cell modules include connecting wires, conductive paste used in wafer-based solar cell modules, conductive coatings used in thin film solar cells, and back reflector films. Silver is one oxidizable metal that is often present in these metal components. When in contact with an oxidizable metal component, many encapsulants tend to discolor over time. Poly(vinyl butyral) (PVB) is one such encapsulant.

Without wishing to be held to theory, it is hypothesized that discoloration results when metal cations produced by oxidation of the metal component diffuse into the encapsulant layer. The metal ions are reduced to form small particles of the elemental metal. These small particles cause the discoloration. See, for example, Steppan, J. J., et al., “A Review of Corrosion Failure Mechanisms during Accelerated Tests,” J. Electrochem. Soc.: SOLID STATE SCIENCE AND TECHNOLOGY 1987, 134(1), 175-190. More specifically, in the case of silver components in contact with PVB encapsulants, Ag^{o} comprised in the silver component is oxidized, under high voltage and high moisture conditions, to form Ag⁺ ions that migrate into the PVB encapsulant. Once in the PVB encapsulant, the Ag⁺ ions are then reduced to metallic silver) (Ag^{o}). The metallic silver, which may be in the form of nano-sized silver particles, is believed to cause the discoloration.

Discoloration of the encapsulant in solar cell modules is not desirable, however, because it decreases the transmission of light, and because it may be considered aesthetically unpleasing. Thus, solar cell modules have been improved by providing their metal components with a nickel-vanadium alloy coating, which is resistant to oxidation. Imperfections in this coating frequently occur and are difficult to identify, however. The migration of oxidizing agents and metal cations through the pinholes and other flaws in the nickel-vanadium coating allows discoloration to occur despite this preventive measure.

Accordingly, solar cell modules with encapsulants that resist discoloration when in prolonged contact with oxidizable metal components have been developed. In particular, additives that prevent or reduce the reduction of metal cations are known. For example, unsaturated heterocycles, hindered amines, chelating agents, reducing agents and aldehyde scavengers have been used to reduce discoloration of polymeric encapsulants in contact with oxidizable metals. See U.S. patent application Ser. Nos. 12/692,041, 12/692,047, and 12/692,069, filed on Jan. 22, 2010; 12/945,404, filed on Nov. 12, 2010; and the U.S. patent application claiming priority to U.S. Prov. Patent Appln. No. 61/426,239, filed on Dec. 22, 2010 (Attorney Docket No. PP0096 USPRV). The inclusion of these additives in the polymeric encapsulants is believed to reduce the oxidation of the metal component or the formation of the elemental metals from the metal cations. Thus, the resulting discoloration of the encapsulant is mitigated.

These publications describe processes in which the beneficial additives are combined with the polymeric encapsulant, typically in a bulk extrusion process. In this approach, the encapsulant formulation is tailored to the physical conformation of the solar cell module. As a result, the encapsulants are the products of custom formulations and syntheses. It would also be efficient and economical to manufacture and use fewer grades of standard encapsulant materials, however. Therefore, a need exists for an inexpensive and flexible method of providing encapsulants that are in contact with metal components in solar cell modules with resistance to discoloration over time.

### SUMMARY OF THE INVENTION

Accordingly, provided herein is a process for fabricating a solar cell module that is resistant to discoloration. The solar cell module comprises a solar cell assembly and an encapsulant. The solar cell assembly in turn comprises a solar cell and a metal component. The encapsulant is in contact with the metal component. The process comprises the step of applying an additive that prevents or reduces discoloration to the encapsulant or to the metal component. Further provided is a solar cell module that is a product of the process described herein.

### DETAILED DESCRIPTION OF THE INVENTION

Unless otherwise defined, all technical and scientific terms used herein have the same meanings that are commonly understood by one of ordinary skill in the art to which this invention belongs. In case of conflict, the specification, including definitions, will control.

Although methods and materials similar or equivalent to those described herein can be used in the practice or testing of the invention, suitable methods and materials are described herein.

Unless stated otherwise, all percentages, parts, ratios, etc., are by weight.

When an amount, concentration, or other value or parameter is given as either a range, preferred range or a list of upper preferable values and lower preferable values, this is to be understood as specifically disclosing all ranges formed from any pair of any upper range limit or preferred value and any lower range limit or preferred value, regardless of whether ranges are separately disclosed. Where a range of numerical values is recited herein, unless otherwise stated, the range is intended to include the endpoints thereof, and all integers and fractions within the range. It is not intended that the scope of the invention be limited to the specific values recited when defining a range.

When the term “about” is used in describing a value or an end-point of a range, the disclosure should be understood to include the specific value or end-point referred to.

As used herein, the terms “comprises,” “comprising,” “includes,” “including,” “containing,” “characterized by,” “has,” “having” or any other variation thereof, are intended to cover a non-exclusive inclusion. For example, a process, method, article, or apparatus that comprises a list of elements is not necessarily limited to only those elements but may include other elements not expressly listed or inherent to such process, method, article, or apparatus.

The term “or”, as used herein, is inclusive; that is, the phrase “A or B” means “A, B, or both A and B”. Exclusive “or” is designated herein by terms such as “either A or B” and “one of A or B”, for example.

The transitional phrase “consisting essentially of” limits the scope of a claim to the specified materials or steps and those that do not materially affect the basic and novel characteristic(s) of the claimed invention.

Where applicants have defined an invention or a portion thereof with an open-ended term such as “comprising,” it should be readily understood that unless otherwise stated the description should be interpreted to also describe such an invention using the terms “consisting essentially of” and “consisting of”.

The articles “a” and “an” may be employed in connection with various elements and components of compositions, processes or structures described herein. This is merely for convenience and to give a general sense of the compositions, processes or structures. Such a description includes “one or at least one” of the elements or components. Moreover, as used herein, the singular articles also include a description of a plurality of elements or components, unless it is apparent from a specific context that the plural is excluded.

As used herein, the term “copolymer” refers to polymers comprising copolymerized units resulting from copolymerization of two or more comonomers. Such copolymers include dipolymers, terpolymers or higher order copolymers. In this connection, a copolymer may be described herein with reference to its constituent comonomers or to the amounts of its constituent comonomers, for example “a copolymer comprising ethylene and 18 weight % of acrylic acid”, or a similar description. Such a description may be considered informal in that it does not refer to the comonomers as copolymerized units; in that it does not include a conventional nomenclature for the copolymer, for example International Union of Pure and Applied Chemistry (IUPAC) nomenclature; in that it does not use product-by-process terminology; or for another reason. As used herein, however, a description of a copolymer with reference to its constituent comonomers or to the amounts of its constituent comonomers means that the copolymer contains copolymerized units (in the specified amounts when specified) of the specified comonomers. It follows as a corollary that a copolymer is not the product of a reaction mixture containing given comonomers in given amounts, unless expressly stated in limited circumstances to be such.

Provided herein is a process for fabricating a solar cell module. The solar cell module comprises a solar cell assembly and an encapsulant. The encapsulant is a polymeric encapsulant. The solar cell assembly, in turn, comprises a solar cell and a metal component. The metal component is in contact with the encapsulant. The solar cell assembly is fully or partially encapsulated by a polymeric encapsulant layer or layers, and the metal component is at least partially in contact with the encapsulant layer or layers.

Solar cell modules are generally produced by lamination processes. In a typical lamination process, the constituent parts of the solar cell module are stacked in layers, and the layers are adhered together by means of applying one or more of heat, vacuum, or pressure to the stack. The process described herein further comprises the step of applying one or more additives to the surface of the encapsulant or to the surface of the metal component that is in contact with the encapsulant. The additive(s) decrease the oxidation of the metal component, the formation of the elemental metals from the metal cations, or the re-deposition of the metal into particles that are sufficiently large to have an effect on the optical properties of the encapsulant. Preferably, the additive(s) prevent one or more of these deleterious effects.

The term “solar cell” as used herein includes any article that converts light into electrical energy. Solar cells useful in the solar cell assemblies and modules described herein include, but are not limited to, wafer-based solar cells (e.g., c-Si or mc-Si based solar cells), thin film solar cells (e.g., a-Si, μc-Si, CdTe, or CI(G)S based solar cells), and organic solar cells. In principle, however, any type of solar cell known in the art is suitable for use in the solar cell modules described herein. The solar cells include, but are not limited to, those described in U.S. Pat. Nos. 4,017,332; 4,179,702; 4,292,416; 6,123,824; 6,288,325; 6,613,603; and 6,784,361, U.S. Patent Publication Nos. 2006/0213548; 2008/0185033; 2008/0223436; 2008/0251120; and 2008/0271675; and PCT Patent Application Nos. WO2004/084282 and 2007/103598.

Within the solar cell layer, the solar cells may be electrically interconnected and/or arranged in a flat plane. In addition, the solar cell layer may further comprise electrical wiring, such as cross ribbons and bus bars. Monocrystalline silicon (c-Si), poly-crystalline silicon (poly-Si), multi-crystalline silicon (mc-Si) and ribbon silicon are the materials used most commonly in forming traditional wafer-based solar cells. Photovoltaic modules derived from wafer-based solar cells often comprise a series of self-supporting wafers (or cells) that are soldered together. The wafers generally have a thickness of between about 180 and about 240 μm.

Thin film solar cells are commonly formed from materials that include amorphous silicon (a-Si), microcrystalline silicon (μc-Si), cadmium telluride (CdTe), copper indium selenide (CuInSe₂ or CIS), copper indium sulfide, copper indium/gallium diselenide (CuInₓGa₍₁₋ₓ₎Se₂ or GIGS), copper indium/gallium disulfide, light absorbing dyes, and organic semiconductors. Thin film solar cells with a typical thickness of less than 2 μm are produced by depositing the semiconductor layers onto a superstrate or substrate formed of glass or a flexible film.

In either configuration, the solar cell assembly comprises the solar cell(s) and their associated electrical connections. Any of these electrical connections may be a metal component. More broadly, the term “metal component”, as used herein, refers to a constituent part or to any sub-combination of the constituent parts of the solar cell assembly or of the solar cell module that comprises an elemental metal. The term “silver component” refers to a metal component that comprises elemental silver. The terms “elemental silver”, “metallic silver”, and “Ag⁰” are synonymous and are used interchangeably herein. The elemental metal or elemental silver may be present in substantially neat or pure form, for example as they are used in a reflector film. Alternatively, they may be compounded, for example with a non-metallic material such as a carrier or a filler, or they may be present in a solid solution, in an alloy, in crystalline form, as a powder or as a flake, as the continuous or dispersed phase of a dispersion, or in any other morphology. For example, the solder material used in some connecting wires is a silver and aluminum alloy containing as little as about 2 wt % of silver.

The metal component may be any one or more of the electrical connections, including without limitation solder, connecting wires, transparent conductive oxides, cross ribbons, bus bars, conductive paste, metal conductive coatings, and the like, whether included in the solar cell assembly by association with the solar cells or not. Another metal component of photovoltaic modules, although not one that is typically part of the solar cell assembly, is the metal reflector film.

The conductive paste, which is typically used in wafer-based solar cells, is a conductive film deposited on the front sun-facing or back non-sun-facing side of solar cells to efficiently contact the solar cells and transport the photo-generated current. The front conductive paste, for example, may comprise an elemental metal, such as silver.

The term “connecting wires” as used herein also includes the solder materials used to connect the individual wires together or to anchor the wires onto the solar cells. The connecting wires, which may be included in both wafer-based solar cells and thin film solar cells, are typically soldered on the surface of the solar cells to provide electrical connections between individual solar cells and to lead the photo-generated current out of the modules. In certain solar cell modules, the connecting wires (including its solder material), and especially the solder material, may comprise a metal, such as silver or a silver alloy.

During the construction of thin film solar cells, a first conductive layer (e.g., a transparent conductive oxide (TCO) or metal coating) is first coated on the substrate before the photon absorbing materials is deposited thereon. Further, during the construction of the solar cells, a second conductive layer (e.g., a TCO or metal coating) is further deposited on the photon absorbing materials. The metal component may be one or both of these two metal conductive coatings.

Metal back reflector films are often incorporated in thin film solar cells to reflect the photons that have passed around or through the solar cells back onto the solar cells, thereby improving power generating efficiency. In certain solar cell modules, the metal back reflector film is formed by sputtering a silver layer or a silver-comprising layer on the solar cells. Accordingly, these metal back reflector films may be considered part of the solar cell assembly.

Moreover, the metal component may be completely or partially in contact with the encapsulant. For example, “partially in contact with” indicates that at least about 3.6×10⁻⁵% of the metal component's surface area is in contact with the encapsulant. This amount corresponds to the calculated area of scribe lines in a thin film cell, although it is also used herein to indicate a minimum surface area of contact for other metal components and in different types of solar cell modules. In contrast, the metal component may be completely in contact with the encapsulant, for example in a solar cell module in which substantially 100% of the surface area of a reflector film is in contact with the encapsulant. When used without modification, however, as in the term “the silver component is in contact with the encapsulant,” for example, any non-zero level of contact is indicated. Stated alternatively, any non-zero percentage of the metal component's surface area may be in contact with the encapsulant.

In one module, the solar cells are wafer-based solar cells, and the metal component is a silver component that may be a conductive paste deposited thereon, or it may be one or more connecting wires. The silver component is in contact with the encapsulant. Further, the solar cell assembly, which comprises the wafer-based solar cells and the silver component, and which is encapsulated by the encapsulant, may be further sandwiched between two protective outer layers. The protective outer layers may also be referred to as the front and back sheets.

Any suitable encapsulant may be used in the methods described herein. Suitable encapsulants include, without limitation, those described in detail in U.S. patent application Ser. No. 12/847,619, filed on Jul. 30, 2010. Examples of suitable encapsulants include, without limitation, olefin unsaturated carboxylic acid copolymers, ionomers of olefin unsaturated carboxylic acid copolymers, ethylene vinyl acetate copolymers, poly(vinyl acetals) (including acoustic grade poly(vinyl acetals)), polyurethanes, polyvinylchlorides, polyethylenes (e.g., linear low density polyethylenes), polyolefin block copolymer elastomers, copolymers of α-olefins and ethylenically unsaturated carboxylic acid esters (e.g. ethylene methyl acrylate copolymers and ethylene butyl acrylate copolymers), silicone elastomers, epoxy resins, and combinations of two or more thereof. Preferred are polyolefins, ethylene acid copolymers, ionomers of ethylene acid copolymers, copolymers of ethylene and vinyl acetate (EVA), and poly(vinyl acetals). More preferred are encapsulants that have a greater tendency towards discoloration, such as EVA and poly(vinyl acetals), including poly(vinyl butyrals) (PVB).

Suitable PVB resins for use as encapsulants in solar cells have a weight average molecular weight of about 30,000 Da, or about 45,000 Da, or about 200,000 Da to about 600,000 Da, or about 300,000 Da, as determined by size exclusion chromatography using low angle laser light scattering. The PVB may comprise about 12 wt %, or about 14 wt %, or about 15 wt %, to about 23 wt %, or about 21 wt %, or about 19.5 wt %, or about 19 wt % of hydroxyl groups calculated as polyvinyl alcohol (PVOH). The hydroxyl number can be determined according to standard methods, such as ASTM D1396-92 (1998). In addition, the PVB used here may include up to about 10%, or up to about 3% of residual ester groups, calculated as polyvinyl ester, typically acetate groups, with the balance being butyraldehyde acetal. The PVB may further comprise a minor amount of acetal groups other than butyral, for example, 2-ethyl hexanal, as described in U.S. Pat. No. 5,137,954. PVB can be produced as described in U.S. Pat. Nos. 3,153,009 and 4,696,971, for example.

PVB encapsulants typically include a plasticizer. Any suitable plasticizer may be used. See, e.g., U.S. Pat. Nos. 3,841,890; 4,144,217; 4,276,351; 4,335,036; 4,902,464; 5,013,779; and 5,886,075. Among those commonly used plasticizers are esters of a polybasic acid or a polyhydric alcohol. Specific examples of suitable plasticizers include, but are not limited to, diesters obtained from the reaction of triethylene glycol or tetraethylene glycol with aliphatic carboxylic acids having from 6 to 10 carbon atoms; diesters obtained from the reaction of sebacic acid with aliphatic alcohols having from 1 to 18 carbon atoms; oligoethylene glycol di-2-ethylhexanoate; tetraethylene glycol di-n-heptanoate; dihexyl adipate; dioctyl adipate; dibutoxy ethyl adipate; mixtures of heptyl and nonyl adipates; dibutyl sebacate; tributoxyethyl-phosphate; isodecylphenylphosphate; triisopropylphosphite; polymeric plasticizers, such as the oil-modified sebacid alkyds; mixtures of phosphates and adipates; mixtures of adipates and alkyl benzyl phthalates; and combinations of two or more of the above. Preferred plasticizers include triethylene glycol di-2-ethylhexanoate, tetraethylene glycol di-n-heptanoate, dibutyl sebacate, and combinations of two or more thereof. More preferred plasticizers include triethylene glycol di-2-ethylhexanoate, tetraethylene glycol di-n-heptanoate, and combinations thereof. A plasticizer of note is triethylene glycol di-2-ethylhexanoate.

The amount of plasticizer in the PVB composition is about 15 wt %, or about 20 wt %, or about 25 wt % to about 45 wt %, or about 35 wt %, or about 30 wt %, based on the total weight of the PVB composition.

The polymeric encapsulant, whether it comprises PVB or another suitable polymer, may further comprise one or more additives, including one or more UV absorbers at a level ranging from about 0.01 wt %, or about 0.05 wt %, or about 0.08 wt % to about 1 wt %, or about 0.8 wt %, or about 0.5 wt %. The encapsulant may further comprise one or more thermal stabilizers at a level ranging from about 0.01 wt %, or about 0.05 wt %, or about 0.08 wt % to about 1 wt %, or about 0.8 wt %, or about 0.5 wt %. The encapsulant may yet further comprise one or more unsaturated heterocyclic compounds at a level of about 0.5 to about 2 wt %, preferably about 0.1 to about 2 wt %. The encapsulant may yet further comprise one or more hindered amines at a level of up to 1 wt %. Alternatively, the hindered amines may be present at a level ranging from about 0.08 wt %, or about 0.1 wt %, or greater than 0.1 wt %, to about 1 wt %, to about 0.8 wt %, or up to about 0.5 wt %. The encapsulant may yet further comprise one or more chelating agents at a level ranging from about 0.01 wt %, or about 0.05 wt %, or about 0.08 wt % to about 1 wt %, or about 0.8 wt %, or about 0.5 wt %. The encapsulant may yet further comprise one or more reducing agents at a level of at least about 0.01, 0.02, 0.05, 0.1, 0.2, 0.3, 0.4, or 0.5 wt % up to about 5.0, 4.0, 3.0, 2.0 or 1.0 wt %. The encapsulant may yet further comprise one or more aldehyde scavengers at a level of about 0.001 wt %, 0.01 wt %, 0.1 wt %, 0.2 wt %, 0.3 wt %, 0.4 wt %, 0.5 wt %, 0.6 wt %, 0.7 wt %, 0.8 wt %, 0.9 wt %, 1.0 wt %, 1.25 wt %, 1.50 wt %, 1.75 wt %, 2.0 wt %, 2.5 wt %, 3.0 wt %, 3.5 wt %, 4.0 wt %, 4.5 wt %, 5.0 wt %, 5.5 wt %, 6.0 wt %, 6.5 wt %, 7.0 wt %, 7.5 wt %, 8.0 wt %, 8.5 wt %, 9.0 wt %, 9.5 wt %, or 10.0 wt %. The amounts of the additives are based on the total weight of the encapsulant.

Examples of suitable and preferred additives are set forth in U.S. patent application Ser. Nos. 12/692,041, 12/692,047, and 12/692,069, filed on Jan. 22, 2010; 12/945,404, filed on Nov. 12, 2010; and U.S. Provisional Appln. No. 61/426,239, filed on Dec. 22, 2010 (Attorney Docket No. PP0096 USPRV), cited above. Briefly, however, examples of suitable UV absorbers include, but are not limited to, benzotriazole derivatives, hydroxybenzophenones, hydroxyphenyl triazines, esters of substituted and unsubstituted benzoic acids, and mixtures of any two or more of these suitable UV absorbers. Significantly, the benzotriazole derivatives that are useful as UV absorbers are 2-H substituted benzotriazole derivatives. Therefore, they are not included in the definitions of non-2-H substituted benzotriazole derivatives and of unsaturated heterocyclic compounds that are set forth above.

Suitable thermal stabilizers may also be referred to as phenolic antioxidants and are well known in the industry. Examples of suitable thermal stabilizers include, but are not limited to, Irganox™ 1010, Irganox™ 1035, Irganox™ 1076, Irganox™ 1081, Irganox™ 1098, Irganox™ 1135, Irganox™ 1330, Irganox™ 1425 WL, Irganox™ 1520, Irganox™ 245, Irganox™ 3114, Irganox™ 565, Irganox™ E 201, or Irganox™ MD 1024 manufactured by the BASF Corporation of Florham Park, N.J. (“BASF”), Lowinox™ 1790, Lowinox™ 22M46, Lowinox™ 44B25, Lowinox™ CA22, Lowinox™ CPL, Lowinox™ HD 98, Lowinox™ MD24, Lowinox™ TBM-6, or Lowinox™ WSP, manufactured by Chemtura (Middlebury, Conn.), Cyanox™ 1741, Cyanox™ 2246, or Cyanox™ 425, manufactured by Cytec, or mixtures of any thereof. Thermal stabilizers of note include Lowinox™ 1790, Lowinox™ 22M46, Lowinox™ 44B25, Lowinox™ CA22, Lowinox™ CPL, Lowinox™ HD 98, Lowinox™ MD24, Lowinox™ TBM-6, or Lowinox™ WSP, or mixtures of any thereof. One preferred thermal stabilizer is octylphenol. Another preferred thermal stabilizer is butylated hydroxytoluene (BHT).

Preferred hindered amines include secondary or tertiary hindered amines. Examples of suitable secondary hindered amines include, but are not limited to, 2,2,6,6-tetramethylpiperadine, 2,2,6,6-tetramethylpiperadinol, and mixtures thereof. Examples of suitable tertiary hindered amines include, but are not limited to, 2-(dimethylamino)pyridine, 4-(dimethylamino)pyridine, N-butyl piperidine, N,N-diethyl cyclohexylamine, and mixtures of any thereof. In one preferred module, the hindered amines are hindered amine light stabilizers (HALS), which are typically secondary, tertiary, acetylated, N-hydrocarbyloxy substituted, hydroxy substituted, N-hydrocarbyloxy substituted, or other substituted cyclic amines which further incorporate steric hindrance, generally derived from aliphatic substitution on the carbon atoms adjacent to the amine function. HALS are well known within the art and commercially available, for example from BASF, under the tradenames Tinuvin™ and Chimassorb™.

Preferred chelating agents include, but are not limited to, ethylenediamine-tetraacetic acid (EDTA), ethylenediamine monoacetic acid, ethylenediamine diacetic acid, ethylenediamine triacetic acid, ethylene diamine, tris(2-aminoethyl)amine, diethylenetriaminepentacetic acid, or mixtures of any thereof. One preferred encapsulant composition comprises PVB and EDTA.

The reducing agent for the polymeric encapsulant material and for the poly(vinyl butyral) composition may be selected from any material capable of reducing the oxidizable metal. Preferably, the reducing agent is selected from hydroquinones, phenidone, formic acid, citric acid, ascorbic acid, polysaccharides, primary amines, secondary amines, lithium aluminum hydride, aldehydes, formaldehyde, diboranes, dimethylaminoborane, iron metal, reducing sugars, glucose, Grignard reagents, hypophosphorous acid and derivatives thereof, hydrazine, hydroxylamines, lithium amide, lithium borohydride, calcium hydride, sodium amide, zinc metal, triethylsilane, silanehydrides, acrylamides, poly(acrylamides), poly(vinyl pyrrolidone), dimethyl formamide, polyols, glycols, glycerol, sodium dithionate, sodium sulfide, pyrocatechol and the like and combinations of two or more suitable reducing agents. More preferably, the reducing agent is selected from hydroquinones. Still more preferably, the reducing agent is hydroquinone.

The term “aldehyde scavenger”, as used herein, refers to compounds and materials that reduce the amount of free aldehydes (R—CH(O)) in aldehyde-containing or aldehyde-generating compositions and structures. Suitable aldehyde scavengers include, without limitation, those described in U.S. Patent Appln. Publn. No. 2002/0123543 and in Intl. Patent Appln. Publn. No. 2002/088237. Preferred aldehyde scavengers include, without limitation, anthranilamide; salicylamide; salicylanilide; o-phenylene-diamine; 3,4-diaminobenzoic acid; 1,8-diaminonaphthalene; o-mercapto-benzamide; N-acetylglycinamide; malonamide; 3-mercapto-1,2-propane-diol; histidine; tryptophan; 4-amino-3-hydroxybenzoic acid; 4,5-dihydroxy-2,7-naphthalenedisulfonic acid and its disodium salt; biuret (H₂NC(O)NHC(O)NH₂); 2,3-diaminopyridine; 1,2-diaminoanthraquinone; dianilinoethane; allantoin; and 2-amino-2-methyl-1,3-propanediol.

Finally, preferred unsaturated heterocyclic compounds include, without limitation, 1H-benzotriazole or a non-2-H substituted benzotriazole derivative having a formula of:

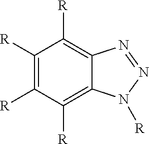

or imidazole or an imidazole derivative having a formula of:

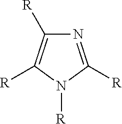

wherein R represents a hydrogen atom or a substituent; wherein, when the unsaturated heterocyclic compound comprises more than one substituent R, the substituents R are identical or different; and wherein the substituents R are selected from the group consisting of alkyl groups that are branched or unbranched, linear or cyclic; singly or multiply unsaturated hydrocarbon groups that are unbranched or branched, linear or cyclic, aromatic or non-aromatic; amino groups; hydroxyl groups; alkoxy groups; and halogen atoms; and further wherein one or more of the substituents R may optionally be substituted with one or more halogen atoms that may be the same or different or with one or more branched or unbranched alkyl groups comprising from 1 to 4 carbon atoms that may be the same or different. More preferably, R represents hydrogen or a substituent selected from the group consisting of branched and linear alkyl groups having from 1 to 4 carbon atoms. 1H-Benzotriazole, non-2H-substituted benzotriazole derivatives, imidazole, and imidazole derivatives are preferred unsaturated heterocyclic compounds. Specific examples of preferred unsaturated heterocyclic compounds include, without limitation, 1H-benzotriazole; 5-methyl-1H-benzotriazole; imidazole; 2-methyl imidazole; and 1H-1,2,3-triazole. 1H-Benzotriazole is a more preferred unsaturated heterocyclic compound.

In addition to the plasticizer and the additives listed above, the encapsulant may further comprise one or more of any other suitable additives, including, but not limited to, adhesion control additives, surface tension controlling agents, processing aids, flow enhancing additives, lubricants, pigments, dyes, flame retardants, impact modifiers, nucleating agents, anti-blocking agents such as silica, dispersants, surfactants, coupling agents, reinforcement additives, such as glass fiber, fillers and the like. These additives, suitable concentrations of the additives, and methods for incorporating them into the encapsulant are described in the Kirk Othmer Encyclopedia of Chemical Technology, 5^{th} Edition, John Wiley & Sons (New Jersey, 2004), for example.

As is described above, the solar cell assembly is fully or partially encapsulated by a polymeric encapsulant layer or layers. A “fully encapsulated” solar cell assembly is laminated or sandwiched between two encapsulant layers. Generally, the area of the largest surface of the solar cell assembly is smaller than that of some other components of the solar cell module, such as, for example, the substrate or superstrate, or the front or back protecting layers, or the encapsulant layer(s) before or after lamination. Therefore, in modules comprising fully encapsulated assemblies, the two encapsulant layers may come in contact with each other over the edges of the solar cell assembly and form a seal around the edges of the solar cell module. When the area of the largest surface of the encapsulant layers is larger than that of the solar cell assembly, the contact between them may be established in the stacked, unlaminated solar cell module. Alternatively, when the greatest two-dimensional surface area of the encapsulant layers is smaller than that of the solar cell assembly, the contact between them may not be established until the encapsulant layers melt and flow under the heat and pressure of the solar cell module lamination process. Those of skill in the art will be able to take account of the changes necessitated in the above description by solar cell assemblies having a significant thickness.

A “partially encapsulated” solar cell assembly, which comprises solar cells (such as thin film solar cells) and is deposited on a substrate (or superstrate), has one side that is opposite from the substrate (or superstrate) laminated to an encapsulant layer so that the solar cell assembly is sandwiched between the substrate (or superstrate) and the encapsulant layer. In modules comprising partially encapsulated assemblies, the encapsulant layer may come in contact with the substrate (or superstrate) of the solar cell assembly over the edges of the solar cell module and form a seal around the edges of the solar cell assembly. Again, depending on the relative surface areas of the substrate (superstrate), the solar cell assembly and the encapsulant layer, the edge seal may form before or after the lamination process that forms the solar cell module.

In one solar cell module, for example, the encapsulant layer(s) are formed from PVB sheets and the encapsulated solar cell assembly is formed by laminating one or both sides of the solar cell assemblies to the PVB sheet(s). The PVB sheets may have a thickness of about 0.25 to about 1.2 mm.

The photovoltaic modules may further include other layers, as necessary to fulfill the design requirements for the end use for which the module is intended. For example, a second encapsulant layer may be the same as, or different from, the encapsulant layer that is present in the photovoltaic modules. Any optional additional encapsulant layers used in the photovoltaic modules described herein may each comprise a polymeric material independently selected from the group consisting of olefin unsaturated carboxylic acid copolymers, ionomers of olefin unsaturated carboxylic acid copolymers, ethylene vinyl acetate copolymers, poly(vinyl acetals) (including acoustic grade poly(vinyl acetals)), polyurethanes, polyvinylchlorides, polyethylenes (e.g., linear low density polyethylenes), polyolefin block copolymer elastomers, copolymers of α-olefins and ethylenically unsaturated carboxylic acid esters (e.g. ethylene methyl acrylate copolymers and ethylene butyl acrylate copolymers), silicone elastomers, epoxy resins, and combinations of two or more thereof. Preferred additional encapsulant layers are described in detail in U.S. patent application Ser. No. 12/847,619, filed on Jul. 30, 2010. More preferred materials for additional encapsulant layers include, without limitation, ionomers available from E.I. du Pont de Nemours and Company of Wilmington, Del., USA (“DuPont”) under the Surlyn® trademark and as DuPont™ PV5300, PV5400 and PV8600 Series ionomer-based sheeting; ethylene/vinyl acetate copolymers available from DuPont under the Elvax® trademark; and ethylene/alkyl acrylate copolymers available from DuPont under the Elvaloy® AC trademark.

The composition used in the optional additional encapsulant layer may further include one or more additives. Suitable additives and quantities are as described above with respect to the encapsulant layer.

Another type of additional layer that may be present in the photovoltaic module is one or two outer protective layers, as mentioned above. These protective outer layers may be formed of any suitable sheets or films. Suitable sheets include glass sheets, metal sheets such as aluminum, steel, galvanized steel, ceramic plates, or plastic sheets, such as polycarbonates, acrylics, polyacrylates, cyclic polyolefins (e.g., ethylene norbornene polymers), polystyrenes (preferably polystyrenes prepared in the presence of metallocene catalysts), polyamides, polyesters, fluoropolymers, or combinations of two or more thereof.

Suitable films include metal films, such as aluminum foil, or polymeric films such as those comprising polyesters (e.g., poly(ethylene terephthalate) and poly(ethylene naphthalate)), polycarbonate, polyolefins (e.g., polypropylene, polyethylene, and cyclic polyolefins), norbornene polymers, polystyrene (e.g., syndiotactic polystyrene), styrene-acrylate copolymers, acrylonitrile-styrene copolymers, polysulfones (e.g., polyethersulfone, polysulfone, etc.), nylons, poly(urethanes), acrylics, cellulose acetates (e.g., cellulose acetate, cellulose triacetates, etc.), cellophane, silicones, poly(vinyl chlorides) (e.g., poly(vinylidene chloride)), fluoropolymers (e.g., polyvinyl fluoride, polyvinylidene fluoride, polytetrafluoroethylene, ethylene-tetrafluoroethylene copolymers, etc.), or combinations of two or more thereof. The polymeric film may be non-oriented, or uniaxially oriented, or biaxially oriented. Some specific examples of suitable polymeric films include, but are not limited to, polyester films (e.g., poly(ethylene terephthalate) films), fluoropolymer films (e.g., Tedlar®, Tefzel®, and Teflon® films available from DuPont. Further, the films may be in the form of a multi-layer film, such as a fluoropolymer/polyester/fluoropolymer multilayer film (e.g., Tedlar®/PET/Tedlar® or TPT laminate film available from Isovolta AG., Austria or Madico, Woburn, Mass.).

In another module, the solar cells are thin film solar cells, and the silver component may be selected from connecting wires, conductive coatings, or back reflector films, or a combination of two or more thereof. In one particular thin film solar cell, the silver component is a conductive coating comprising silver or silver alloy. The silver component may also be a back reflector film comprising silver or silver alloy. Similarly to the above described wafer-based solar cell modules, the thin film solar cell assembly is fully or partially encapsulated by the PVB encapsulant, and the silver component is in contact with the PVB encapsulant. Again, the fully or partially encapsulated thin film solar cell assembly may be further sandwiched between two additional protective outer layers, such as a front or back sheet. Alternatively, the thin film solar cell assembly may be partially encapsulated by the PVB encapsulant, i.e., the side that is opposite from the substrate (or superstrate) is laminated to the PVB encapsulant, and the PVB encapsulant is further laminated to a protective outer layer. Also preferably, the thin film solar cell assembly comprises a reflector film which, in turn, comprises silver and which is in contact with the PVB encapsulant.

In a preferred thin film solar cell module, the light absorbing materials are deposited on a substrate in layers. The substrate may be made of glass, or any suitable metal, or polymeric sheets or films as described above for the protective outer layers. The thin film solar cells may be single-junction or multi-junction (including tandem junction) thin film solar cells. As the spectrum of solar radiation provides photons of varying energies, multi-junction solar cells were developed in which the sunlight passes serially through several solar cell layers. Each separate layer of the multi-junction solar cell is tailored to convert photons of a specific wavelength efficiently to electrical energy. The multi-junction solar cells are usually constructed with layers of different energy gaps. The layers having greater energy gaps are adjacent to the surface through which the light enters the module. The layers having lesser energy gaps are positioned further towards the interior or back of the module.

The photovoltaic module may further comprise other functional film or sheet layers (e.g., dielectric layers or barrier layers) embedded within the module. For example, poly(ethylene terephthalate) films coated with a metal oxide coating, such as those disclosed in U.S. Pat. Nos. 6,521,825 and 6,818,819 and European Patent No. EP1182710, may function as oxygen and moisture barrier layers in the transparent multilayer film laminates or photovoltaic modules.

If desired, a layer of fiber (scrim) may also be included between the solar cell layers and encapsulant layers to facilitate deaeration during the lamination process or to serve as reinforcement for the encapsulant layers. The fiber may be a woven or nonwoven glass fiber or a networked mat of connected fibers. The use of such scrim layers is disclosed in U.S. Patent Nos. 5,583,057; 6,075,202; 6,204,443; 6,320,115; and 6,323,416 and European Patent No. EP0769818, for example.

Any of the photovoltaic modules described above may be prepared using the methods described herein. These methods include the step of applying one or more additives that prevent or reduce discoloration to the encapsulant or to the metal component. Suitable and preferred additives are described above, with respect to compounding the polymeric encapsulant. In particular, the additives are selected from the group consisting of reducing agents, unsaturated heterocyclic compounds, aldehyde scavengers, hindered amine light stabilizers, and chelating agents.

The additives may be present internally or externally on the encapsulant. The additives that are applied to the surface of the encapsulant or the metal component may be the same as or different from the additives that are included in the bulk of the encapsulant.

The additive(s) may be applied to the surface(s) of the metal components or the encapsulant sheet by any suitable process, including, without limitation, wiping; brushing; painting; dip coating; extrusion or co-extrusion coating; air knife coating; bar coating; squeeze coating; impregnating; reverse roll coating; transfer roll coating; kiss coating; casting; spraying; spin coating; Dahlgren; thermal transfer printing; silk screen; lithography; flexographic, gravure and inkjet printing; doctor blade; dye sublimation; xerography; offset printing; intaglio; screen printing; and the like. Suitable and preferred inks and printing methods are described in U.S. patent application Ser. No. 11/725,710, filed on Mar. 19, 2007. Other suitable methods of applying the additives are set forth in International Patent Appln. Publn. Nos. WO200218154, WO200401127, and WO2004018197. Further general information about these application techniques may be found in the Kirk-Othmer Encyclopedia, cited above.

When the additives are liquids at room temperature, they may be applied neat or in solution to the surface of the encapsulant sheet or to the metal component. Solid additives may be applied as solutions, suspensions, melts or dispersions. Those of skill in the art are able to select a suitable solvent or medium for the additives. In some processes, the additive can be formed into a film that is applied to the encapsulant layer or to the metal component. For example, the additive may be mixed with PVB to form a film that is stacked with or applied to the encapsulant or to the metal component. Alternatively, the additive layer can be applied in the form of a low-viscosity or high-viscosity mixture to a substrate, but preferably as a low-viscosity mixture. To this end, the additive mixtures can be applied in undiluted or minimally diluted form at an elevated temperature or in a more diluted form at a low temperature. When a solvent for the additive(s) or a medium for a dispersion or a suspension is present, it is preferable that the solvent or medium be compatible with the encapsulant. The term “compatible” in this context means that the encapsulant composition, or at least one polymer in the encapsulant composition, is soluble to some degree in the solvent or medium.

In order to adjust the viscosity and the leveling behavior, it is possible for the additive mixtures to be combined with additional components. For example, it is possible to employ polymeric binders and/or monomeric compounds which can be converted into a polymeric binder by polymerization. Examples of suitable binders and compounds are organic-solvent soluble polyesters, cellulose esters, polyurethanes and silicones, including polyether- or polyester-modified silicones. It is preferred to employ polymers that are compatible with or identical to the polymers that are present in the encapsulant. The addition of small amounts of suitable leveling agents may also be advantageous. It is possible to employ from about 0.005 to 1% by weight, in particular from 0.01 to 0.5% by weight of one or more leveling agents, based on the amount of additive(s) in the mixture. Examples of suitable leveling agents are glycols, silicone oils and, in particular, acrylate polymers, such as the acrylate copolymers obtainable under the name Byk 361 or Byk 358 from Byk-Chemie USA of Wallingford, Conn., and the modified, silicone-free acrylate polymers obtainable under the name Tego Flow ZFS 460 from the Tego brand of Degussa AG through Degussa Goldschmidt of Hopewell, Va. Other ingredients that may be used to formulate the additive(s) before applying them to the encapsulant or to the metal component are set forth in U.S. patent application Ser. No. 11/725,710, cited above.

The additive(s), whether formulated or not, are applied to the encapsulant or to the metal component before the components of the photovoltaic module are laminated. When the additive(s) are formulated with volatile compounds, such as solvents, it is preferred to dry the additive layer(s) before the lamination, to prevent the formation of bubbles or other optical flaws during the lamination. Where two or more additive layers are applied, they can be applied and dried individually. Alternatively, it is possible to apply two or more, or all, of the layers to be applied in one application procedure, wet-on-wet, to the encapsulant or metal component, and to carry out conjoint drying. The additive(s) in the individual layers may be the same or different. Casting techniques are particularly suitable for wet-on-wet application of additive layers, especially knife or bar casting techniques, cast-film extrusion or stripper casting techniques, and the cascade casting process.

Finally, the encapsulant or the metal component may be fully or partially coated with the additive(s). Preferably, the metal component is completely coated with the additive(s). Also preferably, at least the portion of the surface of the encapsulant layer that is directly in contact with the metal component is coated.

Any suitable, operative lamination process, including autoclave and non-autoclave processes, may be used to produce the solar cell modules. For example, in a typical lamination process, wafer-based solar cells are first stacked between encapsulant layers. The stack is placed between two protective films or sheets, and this assembly of five layers is then subjected to the lamination process. Further, in an example of the preparation of a thin film solar cell module, the solar cell side of the substrate is stacked adjacent to the encapsulant, and a protective film or sheet is stacked adjacent to the encapsulant. This assembly of three layers is then subjected to the lamination process.

In an example of a suitable lamination process, the stacked assembly of layers is placed into a bag capable of sustaining a vacuum (“a vacuum bag”). The air is drawn out of the bag by a vacuum line or other means, and the bag is sealed while the vacuum is maintained (e.g., at least about 27-28 in Hg (689-711 mm Hg)). The sealed bag is placed in an autoclave at a pressure of about 150 to about 250 psi (about 11.3 to about 18.8 bar), a temperature of about 130° C. to about 180° C., or about 120° C. to about 160° C., or about 135° C. to about 160° C., or about 145° C. to about 155° C., and for a period of about 10 to about 50 min, or about 20 to about 45 min, or about 20 to about 40 min, or about 25 to about 35 min. A vacuum ring may be substituted for the vacuum bag. One type of suitable vacuum bag is disclosed within U.S. Pat. No. 3,311,517. Following the heat and pressure cycle, the air in the autoclave is cooled without adding additional gas to maintain pressure in the autoclave. After about 20 min of cooling, the excess air pressure is vented and the laminates are removed from the autoclave.

Alternatively, the pre-lamination assembly may be heated in an oven at about 80° C. to about 120° C., or about 90° C. to about 100° C., for about 20 to about 40 min. Thereafter, the heated assembly is passed through a set of nip rolls so that the air in the void spaces between the individual layers may be squeezed out, and so that the edge of the assembly may be sealed. The assembly at this stage is referred to as a pre-press.

The pre-press may then be placed in an air autoclave where the temperature is raised to about 120° C. to about 160° C., or about 135° C. to about 160° C., at a pressure of about 100 to about 300 psi (about 6.9 to about 20.7 bar), or preferably about 200 psi (13.8 bar). These conditions are maintained for about 15 to about 60 min, or about 20 to about 50 min. Afterwards, the air in the autoclave is cooled and no further air is added to the autoclave. After about 20 to about 40 min of cooling, the excess air pressure is vented and the laminated products are removed from the autoclave.

The solar cell modules may also be produced through non-autoclave processes. Suitable non-autoclave processes are described, e.g., in U.S. Pat. Nos. 3,234,062; 3,852,136; 4,341,576; 4,385,951; 4,398,979; 5,536,347; 5,853,516; 6,342,116; and 5,415,909; U.S. Patent Publication No. 20040182493; European Patent No. EP1235683 B1; and PCT Patent Publication Nos. WO9101880 and WO03057478. Generally, the non-autoclave processes include heating the pre-lamination assembly and the application of vacuum, pressure or both. For example, the assembly may be successively passed through heating ovens and nip rolls.

Solar cell modules produced by the processes described herein are resistant to discoloration, compared to other solar cell modules that do not include an additive. More specifically, the additives used herein are positioned at the interface between the polymeric encapsulant and the metal component. These additives are believed to reduce or prevent discoloration by mitigating the oxidation of the metal component, or the reduction of its cations, or the re-deposition of the metal into particles that are sufficiently large to have an effect on the optical properties of the encapsulant.

One particular example is a solar cell module comprising a PVB encapsulant and a silver component, in which one or more of the additives described herein has been applied to one or both of the PVB encapsulant and the silver component. When the PVB encapsulant is in prolonged contact with the silver components, the yellowness index (YI) change of the PVB encapsulant is reduced or minimized. The YI for a PVB encapsulant can be determined in accordance with ASTM E313-05, using a 2° observer and using Illuminant C as a light source. These conditions may also be described as “2°/C”. The YI is reported in unitless numbers and must be normalized to a particular sample pathlength for direct comparison. In general, the YI of PVB encapsulants described herein remains about 60 or less, or about 55 or less, or about 50 or less, or 40 or less, or about 30 or less, or about 20 or less, for a sample having a pathlength of 1.0 cm.

The YI of the encapsulant in a solar cell module is difficult to measure in situ, as the yellowness of the other components in the module, such as the coatings, is difficult to deconvolute from that of the encapsulant. In order to avoid this obstacle, it is generally necessary to delaminate the module, isolating the encapsulant. Delamination is also an inconvenient procedure, however. Therefore, the YI of the encapsulant is generally measured using a model system. Both solid encapsulants and polymer solutions may be used as model systems for the YI of encapsulants in solar cell modules.

When a solid encapsulant is used as a model, it is laminated to the silvered side of silver-coated glass sheet, then held under a bias of 1,000 V for 1000 hours at 85° C. and at 85% relative humidity (RH). The solid encapsulants used as models herein have a constant plasticizer concentration, for the validity of the comparison of the encapsulants' YI. The total amount of the additive(s) (unsaturated heterocyclic compound, UV absorber, thermal stabilizer, hindered amine, chelating agent, reducing agent, aldehyde scavenger and the like) is typically about 1% or less of the amount of plasticizer in the solid encapsulants; accordingly, changes in YI due to variation in the amounts of the additives is deemed to be insignificant.

When a polymer solution is used as a model system, a stock solution of neat resin in a suitable solvent is combined with a stock solution of a silver salt and with stock solution(s) of any additive(s) that are included in the solution model. The solution samples are incubated in a hot water bath for 2 to 8 hours, until the yellow color of a negative control sample becomes apparent to the naked eye. The samples are transferred to cuvettes having a pathlength of 1.0 cm, and their spectra are obtained according to the standard method. The concentrations of the polymer and of the silver (calculated as silver ions) in the solution samples are held constant, again for validity of comparison of the solutions' YI. More specifically, when the encapsulant is PVB, the stock solution is made by dissolving neat PVB resin (10 g) in methanol (100 g); methanol is also the solvent for the stock solutions of the silver salt and the additives; and the PVB solution samples are incubated at 60° C.

The Examples below are provided to describe the invention in further detail. These Examples, which set forth a preferred mode presently contemplated for carrying out the invention, are intended to illustrate and not to limit the invention.

### EXAMPLES

Two pre-press assemblies are made. In the first, an as-received layer of Butacite® PVB interlayer sheet, available from DuPont, is stacked against a silver-mirrored glass sheet, in contact with the silvered side of the glass. A lite of float glass is stacked in contact with the surface of the Butacite® sheet that is opposite the silver mirror. The second pre-press assembly is identical to the first, except that the surface of the Butacite® sheet is brushed with a solution of 1H-benzotriazole (1.0M in absolute ethanol) and dried under ambient conditions before the pre-press assembly is stacked. The treated surface of the Butacite® sheet is in contact with the silvered glass surface. The pre-press assemblies are laminated under identical conditions, and the resulting laminates are exposed to 85% relative humidity at 85° C. for 1000 hours. At the end of this time period, the laminate formed from the treated Butacite® sheet is visibly less yellow than the laminate formed from the as-received Butacite® sheet. In addition, the adhesion of the treated interlayer to the silvered glass surface is adequate.

While certain of the preferred embodiments of the present invention have been described and specifically exemplified above, it is not intended that the invention be limited to such embodiments. Various modifications may be made without departing from the scope and spirit of the present invention, as set forth in the following claims.

What is claimed is:

1. A process for making a solar cell module that is resistant to discoloration, said solar cell module comprising a solar cell assembly and a polymeric encapsulant layer, said solar cell assembly comprising a solar cell and a metal component, wherein the polymeric encapsulant layer is in contact with the metal component; said process comprising the step of:
a. applying one or more additives to the polymeric encapsulant layer or to the metal component.

2. The process of claim 1, wherein the metal component is selected from the group consisting of solder, connecting wires, transparent conductive oxides, cross ribbons, bus bars, conductive paste, metal conductive coatings, other electrical connections and metal reflector film.

3. The process of claim 1, wherein the metal component is a silver component.

4. The process of claim 1, wherein the polymeric encapsulant layer comprises a polymer selected from the group consisting of olefin unsaturated carboxylic acid copolymers, ionomers of olefin unsaturated carboxylic acid copolymers, ethylene vinyl acetate copolymers, poly(vinyl acetals) (including acoustic grade poly(vinyl acetals)), polyurethanes, polyvinylchlorides, polyethylenes (e.g., linear low density polyethylenes), polyolefin block copolymer elastomers, copolymers of α-olefins and ethylenically unsaturated carboxylic acid esters (e.g. ethylene methyl acrylate copolymers and ethylene butyl acrylate copolymers), silicone elastomers, and epoxy resins.

5. The process of claim 1, wherein the polymeric encapsulant layer comprises a copolymer of ethylene and vinyl acetate or a poly(vinyl butyral.

6. The process of claim 1, wherein the one or more additives are selected from the group consisting of unsaturated heterocyclic compounds, hindered amines, chelating agents, reducing agents and aldehyde scavengers.

7. The process of claim 6, wherein the one or more additives comprise an unsaturated heterocyclic compound selected from the group consisting of 1H-benzotriazole, a non-2-H substituted benzotriazole derivative having a formula of: 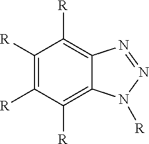
imidazole; and an imidazole derivative having a formula of: 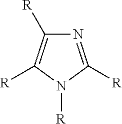
wherein R represents a hydrogen atom or a substituent; wherein, when the unsaturated heterocyclic compound comprises more than one substituent R, the substituents R are identical or different; and wherein the substituents R are selected from the group consisting of alkyl groups that are branched or unbranched, linear or cyclic; singly or multiply unsaturated hydrocarbon groups that are unbranched or branched, linear or cyclic, aromatic or non-aromatic; amino groups; hydroxyl groups; alkoxy groups; and halogen atoms; and further wherein one or more of the substituents R may optionally be substituted with one or more halogen atoms that may be the same or different or with one or more branched or unbranched alkyl groups comprising from 1 to 4 carbon atoms that may be the same or different.

8. The process of claim 6, wherein the one or more additives comprise a hindered amine selected from the group consisting of 2,2,6,6-tetramethylpiperadine, 2,2,6,6-tetramethylpiperadinol, 2-(dimethylamino)pyridine, 4-(dimethylamino)pyridine, N-butyl piperidine, N,N-diethyl cyclohexylamine, and hindered amine light stabilizers.

9. The process of claim 6, wherein the one or more additives comprise a chelating agent selected from the group consisting of ethylenediamine-tetraacetic acid, ethylenediamine monoacetic acid, ethylenediamine diacetic acid, ethylenediamine triacetic acid, ethylene diamine, tris(2-aminoethyl)amine and diethylenetriaminepentacetic acid.

10. The process of claim 6, wherein the one or more additives comprise a reducing agent selected from the group consisting of hydroquinones, phenidone, formic acid, citric acid, ascorbic acid, polysaccharides, primary amines, secondary amines, lithium aluminum hydride, aldehydes, formaldehyde, diboranes, dimethylaminoborane, iron metal, reducing sugars, glucose, Grignard reagents, hypophosphorous acid and derivatives thereof, hydrazine, hydroxylamines, lithium amide, lithium borohydride, calcium hydride, sodium amide, zinc metal, triethylsilane, silanehydrides, acrylamides, poly(acrylamides), poly(vinyl pyrrolidone), dimethyl formamide, polyols, glycols, glycerol, sodium dithionate, sodium sulfide and pyrocatechol.

11. The process of claim 6, wherein the one or more additives comprise an aldehyde scavenger selected from the group consisting of anthranilamide; salicylamide; salicylanilide; o-phenylenediamine; 3,4-diaminobenzoic acid; 1,8-diaminonaphthalene; o-mercaptobenzamide; N-acetylglycinamide; malonamide; 3-mercapto-1,2-propanediol; histidine; tryptophan; 4-amino-3-hydroxybenzoic acid; 4,5-dihydroxy-2,7-naphthalene disulfonic acid and its disodium salt; biuret; 2,3-diaminopyridine; 1,2-diaminoanthraquinone; dianilinoethane; allantoin; and 2-amino-2-methyl-1,3-propanediol.

12. The process of claim 1, wherein the encapsulant further comprises a UV absorber or a thermal stabilizer.

13. The process of claim 1, wherein the one or more additives are applied by a method selected from the group consisting of wiping; brushing; painting; dip coating; extrusion or co-extrusion coating; air knife coating; bar coating; squeeze coating; impregnating; reverse roll coating; transfer roll coating; kiss coating; casting; spraying; spin coating; Dahlgren; thermal transfer printing; silk screen; lithography; flexographic, gravure and inkjet printing; doctor blade; dye sublimation; xerography; offset printing; intaglio; and screen printing.

14. The process of claim 1, further comprising the step of stacking the solar cell assembly and the polymeric encapsulant layer to form a pre-press assembly.

15. The process of claim 14, wherein the pre-press assembly comprises a substrate or superstrate comprising thin film solar cells, the polymeric encapsulant layer, and an outer protective layer; or wherein the pre-press assembly comprises an outer protective layer, the polymeric encapsulant layer, a solar cell assembly, a second polymeric encapsulant layer, and a second outer protective layer, wherein the second polymeric encapsulant layer and the second outer protective layer may be the same as or different from the encapsulant layer and the outer protective layer.

16. The process of claim 14, further comprising the step of laminating the pre-press assembly to form the solar cell module.

17. The process of claim 16 wherein the lamination is carried out in an autoclave process or in a non-autoclave process.

18. A solar cell module produced by the process of claim 1.

19. A pre-press assembly produced by the process of claim 14.

20. A pre-press assembly or a solar cell module produced by the process of claim 15.
